(19) United States
(12) Patent Application Publication
(10) Pub. No.: US 2023/0230904 A1
(43) Pub. Date: Jul. 20, 2023

(54) SEMICONDUCTOR DEVICE

(71) Applicant: Sumitomo Electric Device Innovations, Inc., Yokohama-shi (JP)

(72) Inventor: Akihiro SHINSAI, Yokohama-shi (JP)

(73) Assignee: Sumitomo Electric Device Innovations, Inc., Yokohama-shi (JP)

(21) Appl. No.: 18/095,603

(22) Filed: Jan. 11, 2023

(30) Foreign Application Priority Data
Jan. 17, 2022 (JP) 2022-004995

(51) Int. Cl. H01L 23/495; H01L 23/31; H01L 23/00; H01L 25/16

(52) U.S. Cl. CPC H01L 23/49548; H01L 23/3121; H01L 24/48; H01L 25/16; H01L 2224/48175; H01L 2224/48141

(57) ABSTRACT

A semiconductor device includes a base having a first surface on which the semiconductor element is mounted and a second surface opposite to the first surface, a first edge portion having a step from the first surface toward the second surface in a first region of a peripheral edge of the base, a first terminal that is arranged at a position facing the first edge portion when viewed from a thickness direction of the base, a conductive member for electrically connecting the semiconductor element and the first terminal to each other, and a resin material for sealing a part of the base, the semiconductor element, and a part of the first terminal.

### TECHNICAL FIELD

The present disclosure relates to a semiconductor device.

This application is based upon and claims the benefit of the priority from Japanese Patent Application No. 2022-004995, filed on Jan. 17, 2022, the entire contents of which are incorporated herein by reference.

### BACKGROUND

Japanese Unexamined Patent Publication No. H10-50891 describes a semiconductor device. This semiconductor device includes a lead frame (base) and a semiconductor element mounted on the lead frame. Electrode pads of the semiconductor element are electrically connected to base leads and emitter leads by bonding wires.

### SUMMARY

The present disclosure provides a semiconductor device. A semiconductor device includes: a semiconductor element; a base having a first surface on which the semiconductor element is mounted and a second surface opposite to the first surface; a first edge portion having a step from the first surface toward the second surface in a first region of a peripheral edge of the base; a first terminal that is arranged at a position facing the first edge portion when viewed from a thickness direction of the base; a conductive member for electrically connecting the semiconductor element and the first terminal to each other; and a resin material for sealing a part of the base, the semiconductor element, and a part of the first terminal.

### BRIEF DESCRIPTION OF THE DRAWINGS

FIG. 1 is a plan view schematically showing the configuration of a semiconductor device as an example.

FIG. 2 is a cross-sectional view taken along the line II-II in FIG. 1.

FIG. 3 is a cross-sectional view taken along the line in FIG. 1.

FIG. 4 is a plan view schematically showing the configuration of a semiconductor device in another example.

FIG. 5 is a cross-sectional view taken along the line V-V in FIG. 4.

FIG. 6 is a cross-sectional view taken along the line VI-VI in FIG. 4.

FIG. 7 is a cross-sectional view taken along the line VII-VII in FIG. 4.

### DETAILED DESCRIPTION

For example, in a semiconductor device in which an external terminal, such as an input signal terminal or an output signal terminal, and a semiconductor element are electrically connected to each other by a bonding wire (conductive member), if the length of the bonding wire is long, it is conceivable that the high frequency characteristics will be degraded. On the other hand, if the external terminal is brought closer to the base in order to shorten the length of the bonding wire, it is conceivable that the parasitic capacitance generated between the external terminal and the base will degrade the high frequency characteristics.

In addition, when mounting a surface mount type that is formed of a package covered with a resin material, a portion corresponding to the height of the wire loop (bonding wire) is housed by bending the lead (first terminal). As a result, the thickness of the package increases. Since it is necessary to keep a predetermined distance in a portion where the first terminal and the base overlap each other, the package becomes large.

According to the present disclosure, it is possible to provide a semiconductor device in which the degradation of the high frequency characteristics is suppressed.

A semiconductor device according to an embodiment includes: a semiconductor element; a base having a first surface on which the semiconductor element is mounted and a second surface opposite to the first surface; a first edge portion having a step from the first surface toward the second surface in a first region of a peripheral edge of the base; a first terminal that is arranged at a position facing the first edge portion when viewed from a thickness direction of the base; a conductive member for electrically connecting the semiconductor element and the first terminal to each other; and a resin material for sealing a part of the base, the semiconductor element, and a part of the first terminal.

In the semiconductor device described above, the semiconductor element mounted on the base and the first terminal are electrically connected to each other by the conductive member. The first terminal overlaps the first edge portion forming the peripheral edge of the base when viewed from the thickness direction of the base. Therefore, since the distance between the first terminal and the semiconductor element is reduced, it is possible to reduce the length of the conductive member that connects the first terminal and the semiconductor element to each other. Therefore, it is possible to suppress the degradation of the high frequency characteristics due to the length of the conductive member. The distance between the first region of the first edge portion, which is a portion overlapping the first terminal, and the first terminal may be large. In this configuration, it is possible to suppress the generation of parasitic capacitance between the first terminal and the first region. Therefore, it is possible to suppress the degradation of the high frequency characteristics due to parasitic capacitance.

The semiconductor device described above may further include a second edge portion having a step from the first surface toward the second surface in a second region facing the first region of the peripheral edge of the base; and a second terminal that is arranged at a position facing the second edge portion when viewed from the thickness direction of the base, and is electrically connected to the semiconductor element by the conductive member. A distance along the thickness direction between the second terminal and a second region overlapping the second terminal at the second edge portion of the base when viewed from the thickness direction may be larger than a distance between the second terminal and the first surface in the thickness direction. In this configuration, for example, the first terminal and the second terminal may be used as an input signal terminal and an output signal terminal, respectively. In this case, it is possible to suppress the degradation of the frequency characteristics at both the input signal terminal and the output signal terminal.

On the second surface of the first edge portion of the base, a region not overlapping the first region when viewed from the thickness direction may have a first stepped portion formed stepwise toward the first surface. On the second surface of the second edge portion of the base, a region not overlapping the second region when viewed from the thickness direction may have a second stepped portion formed stepwise toward the first surface. In this configuration, the first stepped portion and the second stepped portion can function as anchors for the resin material.

The first terminal may be one of a plurality of the first terminals. A ground terminal extending from the first edge portion may be provided between the plurality of first terminals. In this configuration, it is possible to suppress interference between the first terminals.

The peripheral edge of the base may include a third edge portion that connects the first edge portion and the second edge portion to each other. The third edge portion may provide a recess portion. A third terminal may be arranged in the recess portion. In this configuration, an increase in the size of the package is suppressed.

The semiconductor device described above may further include a matching circuit mounted on the first surface of the base. The matching circuit may be electrically connected to the semiconductor element and the first terminal. In this configuration, it is possible to perform impedance matching between the semiconductor element and the first terminal.

The first terminal may have a first end portion connected to the semiconductor element and a second end portion facing the first end portion. The first end portion may be arranged at a position facing the first edge portion when viewed from the thickness direction of the base. The second end portion may be arranged at a position not facing the first edge portion when viewed from the thickness direction of the base. In this configuration, an increase in the size of the package is suppressed.

The second surface may be exposed on a front surface of a package covered with the resin material. The first end portion may be arranged inside the resin material. The second end portion may be exposed on a front surface of the package. The first terminal may be arranged so as to be bent in a region between the first end portion and the second end portion. In this configuration, an increase in the size of the package is suppressed.

### DETAILS OF EMBODIMENTS OF THE PRESENT DISCLOSURE

Specific examples of a semiconductor device of the present disclosure will be described below with reference to the accompanying diagrams. In addition, the present invention is not limited to these examples, and is indicated by the appended claims and is intended to include all modifications within the meaning and scope equivalent to the appended claims. In the following description, the same elements will be denoted by the same reference numerals in the description of the diagrams, and repeated description thereof will be omitted.

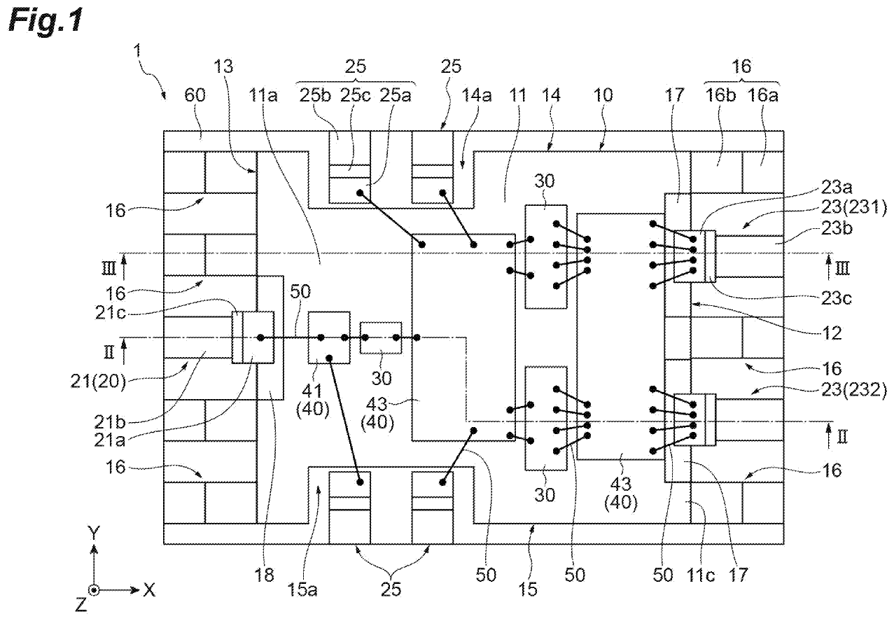

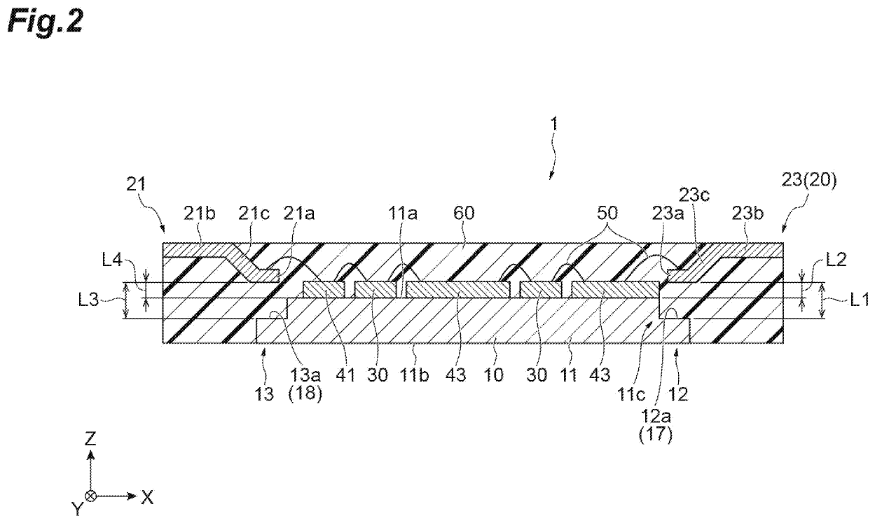

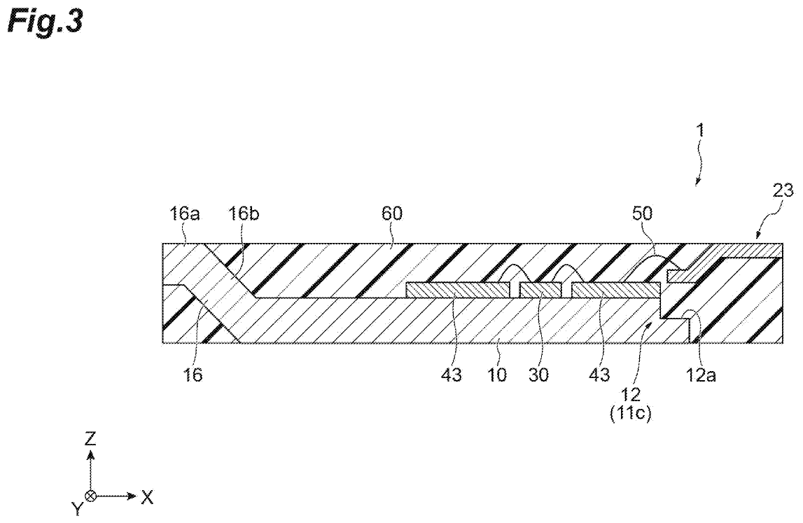

FIG. 1 is a plan view schematically showing the configuration of a semiconductor device as an example. FIG. 2 is a cross-sectional view taken along the line II-II in FIG. 1. FIG. 3 is a cross-sectional view taken along the line in FIG. 1. In the following description, the XYZ orthogonal coordinate system shown in the diagrams may be referred to. As shown in FIGS. 1 to 3, a semiconductor device 1 as an example includes a base 10, an external terminal 20, a semiconductor element 30, a matching circuit board 40, a bonding wire 50, and a resin material 60. In addition, in FIG. 1, a portion covered with the resin material 60 is also drawn with a solid line.

The base 10 as an example is a conductive plate-shaped member. The base 10 can be formed of, for example, copper, a copper-molybdenum alloy, a copper-tungsten alloy, or a stacked material of a copper plate, a molybdenum plate, a tungsten plate, a copper-molybdenum alloy plate, or a copper-tungsten alloy plate. The base 10 in the illustrated example may be formed of copper. In addition, the material of the base 10 is not limited to the above.

The base 10 includes a base body 11 having an approximately rectangular plate shape. The base body 11 has a front surface 11a (first surface) on which the semiconductor element 30 and the matching circuit board 40 are mounted and a back surface 11b (second surface) that is a surface opposite to the front surface 11a. In FIGS. 1 to 3, the front surface 11a and the back surface 11b extend along the XY plane. Therefore, the thickness direction of the base 10 is along the Z direction.

As shown in FIG. 1, a peripheral edge 11c of the base body 11 includes a first edge portion 12 and a second edge portion 13 extending along the Y direction and a third edge portion 14 and a fourth edge portion 15 extending along the X direction. The first edge portion 12 and the second edge portion 13 face each other in the X direction. The third edge portion 14 and the fourth edge portion 15 face each other in the Y direction. The first edge portion 12 and the second edge portion 13 are connected to each other by the third edge portion 14 and the fourth edge portion 15.

The base 10 includes a ground terminal 16. The ground terminal 16 is provided on the peripheral edge 11c of the base body 11. In addition, when viewed from the Z direction, the ground terminal 16 extends outward from the peripheral edge 11c of the base 10. The ground terminal 16 in the illustrated example is provided in the first edge portion 12 and the second edge portion 13. In the illustrated example, one ground terminal 16 is provided at each of the center and both ends of the first edge portion 12 in the Y direction. In the second edge portion 13, one ground terminal 16 is provided at both ends in the Y direction and between both ends and the center. That is, three ground terminals 16 are provided in the first edge portion 12 and four ground terminals 16 are provided in the second edge portion 13. As shown in FIG. 3, the ground terminal 16 includes a first portion 16a extending along the XY plane at a position away from the base body 11 in the Z direction and a second portion 16b connecting the first portion 16a and the base body 11 to each other.

The external terminal 20 includes an input signal terminal 21 and an output signal terminal 23. The input signal terminal 21 is arranged so as to be spaced apart from the second edge portion 13 of the peripheral edge 11c of the front surface 11a of the base 10 when viewed from the Y direction. The input signal terminal 21 overlaps the second edge portion 13 when viewed from the Z direction. As shown in FIG. 2, the input signal terminal 21 includes a first portion 21a extending along the XY plane at a position close to the base body 11 in the Z direction, a second portion 21b extending along the XY plane at a position farther from the base body 11 than the first portion 21a, and a third portion 21c connecting the first portion 21a and the second portion 21b to each other. In the input signal terminal 21 as an example, the first portion 21a faces a part of the second edge portion 13 of the base body 11 in the Z direction. The input signal terminal 21 in the illustrated example is arranged at the center of the base body 11 in the Y direction.

Similarly, the output signal terminal 23 is arranged so as to be spaced apart from the first edge portion 12 of the peripheral edge 11c of the front surface 11a of the base 10 when viewed from the Y direction. The output signal terminal 23 overlaps the first edge portion 12 when viewed from the Z direction. As shown in FIG. 2, the output signal terminal 23 includes a first portion 23a extending along the XY plane at a position close to the base body 11 in the Z direction, a second portion 23b extending along the XY plane at a position farther from the base body 11 than the first portion 23a, and a third portion 23c connecting the first portion 23a and the second portion 23b to each other. In the output signal terminal 23 as an example, the first portion 23a faces a part of the first edge portion 12 of the base body 11 in the Z direction.

In addition, the external terminal 20 includes a power supply terminal 25 (third terminal). In the illustrated example, four power supply terminals 25 are shown. Two power supply terminals 25 are arranged close to the third edge portion 14, and the remaining two power supply terminals 25 are arranged close to the fourth edge portion 15. The power supply terminal 25 as an example is spaced apart from the base body 11 when viewed from the Z direction. In the illustrated example, notch-shaped constricted portions 14a and 15a are provided in the third edge portion 14 and the fourth edge portion 15 of the base body 11, and the power supply terminal 25 is arranged in each of the constricted portions 14a and 15a. For example, the power supply terminal 25 may include a first portion 25a extending along the XY plane at a position close to the base body 11 in the Z direction, a second portion 25b extending along the XY plane at a position farther from the base body 11 than the first portion 25a, and a third portion 25c connecting the first portion 25a and the second portion 25b to each other. The position of the second portion 25b of the power supply terminal 25 in the Z direction may be the same as the position of the second portion 21b of the input signal terminal 21, the position of the second portion 23b of the output signal terminal 23, and the position of the first portion 16a of the ground terminal 16.

The semiconductor element 30 is mounted on the front surface 11a of the base 10. The adhesive for bonding the semiconductor element 30 onto the front surface 11a of the base 10 may be a conductive adhesive, such as silver paste. The semiconductor element 30 may be, for example, a gallium nitride (GaN)-based transistor, but is not limited thereto. For example, the semiconductor element 30 may be a transistor including a substrate formed of Si, SiC, GaN, GaAs, diamond, or the like. The semiconductor element 30 includes electrodes including a drain electrode, a source electrode, and a gate electrode, and is electrically connected to other elements or terminals through these electrodes. In the illustrated example, three semiconductor elements are mounted on the front surface of the base body 11.

The matching circuit board 40 is mounted on the front surface 11a of the base 10. The adhesive for bonding the matching circuit board 40 onto the front surface 11a of the base 10 may be a conductive adhesive such as silver paste. The matching circuit board 40 may be an input circuit board 41 or an output circuit board 43. The input circuit board 41 performs impedance matching between the input signal terminal 21 and the semiconductor element 30. The output circuit board 43 performs impedance matching between the output signal terminal 23 and the semiconductor element 30. The input circuit board 41 and the output circuit board 43 are, for example, parallel plate type capacitor in which an electrode is provided on each of the top and bottom surfaces of a ceramic substrate. In addition, the matching circuit board 40 may be a capacitor formed to have a Si-MOS structure. The matching circuit board 40 is electrically connected to the semiconductor element 30, the external terminal 20, and the power supply terminal 25.

The bonding wire 50 (conductive member) is a member for making the components of the semiconductor device 1 electrically connected to each other. The semiconductor device 1 as an example includes a plurality of bonding wires 50. The bonding wire 50 is formed of, for example, metal such as gold (Au). By the bonding wire 50, the input signal terminal 21 and the input circuit board 41 are electrically connected to each other, the input circuit board 41 and the semiconductor element 30 are electrically connected to each other, the input circuit board 41 and the power supply terminal 25 are electrically connected to each other, the semiconductor element 30 and the output circuit board 43 are electrically connected to each other, the output circuit board 43 and the power supply terminal 25 are electrically connected to each other, and the output circuit board 43 and the output signal terminal 23 are electrically connected to each other. Therefore, the semiconductor element 30 and the input signal terminal 21 and the output signal terminal 23 are electrically connected to each other.

On the base 10 of the semiconductor device 1 as an example, as shown in FIG. 1, the input circuit board 41, the semiconductor element 30, the output circuit board 43, the two semiconductor elements 30, and the output circuit board 43 are mounted in this order from the second edge portion 13 close to the input signal terminal 21 to the first edge portion 12 close to the output signal terminal 23.

The resin material 60 seals the base 10, the semiconductor element 30, the matching circuit board 40 and the external terminal 20. In the semiconductor device 1 as an example, a part of the base 10, the semiconductor element 30, a part of the external terminal 20, and the bonding wire 50 are sealed with the resin material 60. In the semiconductor device 1 as an example, the second portion 21b of the input signal terminal 21, the second portion 23b of the output signal terminal 23, the first portion 16a of the ground terminal 16, and the second portion 25b of the power supply terminal 25 are exposed from the resin material 60. The back surface 11b of the base 10 is also exposed from the resin material 60. The resin material 60 may be, for example, a resin such as a thermosetting epoxy resin.

Hereinafter, the semiconductor device 1 as an example will be described in more detail. As shown in FIG. 2, a distance L1 along the Z direction between the output signal terminal 23 and a first region 12a overlapping the output signal terminal 23 at the first edge portion 12 of the front surface 11a of the base 10 is larger than a distance L2 between the output signal terminal 23 and the front surface 11a of the base 10 in the Z direction. The first region 12a is included in a stepped portion 17 formed in the first edge portion 12. The stepped portion 17 is a portion that is formed stepwise from the front surface 11a toward the back surface 11b. When viewed from the Z direction, the stepped portion 17 has a rectangular shape with short sides along the X direction and long sides along the Y direction. The size of the long side of the stepped portion 17 is larger than the size of the first portion 23a of the output signal terminal 23 in the Y direction.

For example, the stepped portion 17 is formed between a pair of ground terminals 16 arranged with the output signal terminal 23 interposed therebetween in the Y direction. In one example, the stepped portion 17 is formed over the entire region in the Y direction between the pair of ground terminals 16. In the Y direction, the center position of the stepped portion 17 and the center position of the output signal terminal 23 may match each other. The distal end of the output signal terminal 23 may be located between the pair of long sides of the stepped portion 17 in the X direction. In addition, the distal end of the output signal terminal 23 is the edge of the first portion 23a opposite to the third portion 23c. As shown in FIG. 2, the first region 12a of the base 10 and the first portion 23a of the output signal terminal 23 face each other in the Z direction.

Similarly, a distance L3 along the Z direction between the input signal terminal 21 and a second region 13a overlapping the input signal terminal 21 at the second edge portion 13 of the front surface 11a of the base 10 is larger than a distance L4 between the input signal terminal 21 and the front surface 11a in the Z direction. The second region 13a is included in a stepped portion 18 formed in the second edge portion 13. The stepped portion 18 is a portion that is formed stepwise from the front surface 11a toward the back surface 11b. When viewed from the Z direction, the stepped portion 18 has a rectangular shape with short sides along the X direction and long sides along the Y direction. The size of the long side of the stepped portion 18 is larger than the size of the first portion 21a of the input signal terminal 21 in the Y direction.

For example, the stepped portion 18 is formed between a pair of ground terminals 16 arranged with the input signal terminal 21 interposed therebetween in the Y direction. In one example, the stepped portion 18 is formed over the entire region in the Y direction between the pair of ground terminals 16. In the Y direction, the center position of the stepped portion 18 and the center position of the input signal terminal 21 may match each other. The distal end of the input signal terminal 21 may be located between the pair of long sides of the stepped portion 18 in the X direction. In addition, the distal end of the input signal terminal 21 is the edge of the first portion 21a opposite to the second portion 21b. As shown in FIG. 2, the second region 13a of the base 10 and the first portion 21a of the input signal terminal 21 face each other in the Z direction.

For example, the thickness of the base 10, that is, the size of the base 10 in the Z direction may be about 0.2 mm to 0.5 mm, the distance L1 and the distance L3 may be about 0.2 mm to 0.5 mm, and the distance L2 and the distance L4 may be about 0.1 mm to 0.25 mm.

The semiconductor device 1 in the illustrated example includes two output signal terminals 23. For the sake of convenience, the two output signal terminals 23 are referred to as an output signal terminal 231 and an output signal terminal 232. The output signal terminal 231 is arranged between the ground terminal 16 at the center of the first edge portion 12 and the ground terminal 16 on one side in the Y direction. The output signal terminal 232 is arranged between the ground terminal 16 at the center of the first edge portion 12 and the ground terminal 16 on the other side in the Y direction. That is, the ground terminal 16 extending from the base 10 is located between the output signal terminal 231 and the output signal terminal 232.

As described above, the semiconductor device 1 as an example includes: the semiconductor element 30; the base 10 having the front surface 11a (first surface) on which the semiconductor element 30 is mounted and the back surface 11b (second surface) that is a surface opposite to the front surface 11a; the first edge portion 12 having the step from the front surface 11a toward the back surface 11b in the first region 12a of the peripheral edge 11c of the base 10; the output signal terminal 23 (first terminal) that is arranged at a position facing the first edge portion 12 when viewed from the thickness direction (Z direction) of the base 10; the bonding wire 50 for electrically connecting the semiconductor element 30 and the output signal terminal 23 to each other; and the resin material 60 for sealing a part of the base 10, the semiconductor element 30, and a part of the output signal terminal 23. In the semiconductor device 1, since the semiconductor element 30 and output signal terminal 23 are connected by the bonding wire 50 through the matching circuit board 40, the semiconductor element 30 and the output signal terminal 23 are electrically connected to each other.

In a semiconductor device in which signal terminals such as an input signal terminal and an output signal terminal and constituent elements such as a matching circuit board and a semiconductor element are electrically connected to each other by bonding wires, the high frequency characteristics may be degraded when the length of the bonding wire is large. For example, the length of the bonding wire can be reduced by moving the position of the signal terminal closer to the base. However, when the base and the signal terminal overlap each other when viewed from the Z direction, parasitic capacitance is generated between the base and the signal terminal, which can degrade the high frequency characteristics.

In the semiconductor device 1 described above, the semiconductor element 30 mounted on the base 10 and the output signal terminal 23 are electrically connected to each other by the bonding wire 50. The output signal terminal 23 overlaps the first edge portion 12 forming the peripheral edge 11c of the base 10 when viewed from the Z direction. Therefore, since the distance between the output signal terminal 23 and the semiconductor element 30 is reduced, it is possible to reduce the length of the bonding wire 50 that connects the output signal terminal 23 and the semiconductor element 30 to each other. In the illustrated example, it is possible to reduce the length of the bonding wire 50 that connects the output signal terminal 23 and the output circuit board 43 to each other. Therefore, it is possible to suppress the degradation of the high frequency characteristics due to the length of the bonding wire 50. Since the distance along the Z direction between the output signal terminal 23 and the first region 12a of the first edge portion 12, which is a portion overlapping the output signal terminal 23, is large, it is possible to suppress the generation of parasitic capacitance between the output signal terminal 23 and the first region 12a. Therefore, it is possible to suppress the degradation of the high frequency characteristics due to parasitic capacitance.

The semiconductor device 1 as an example includes the second edge portion 13 having the stepped portion 18 from the front surface 11a toward the back surface 11b in the second region 13a facing the first region 12a of the peripheral edge 11c of the base 10; and the input signal terminal 21 (second terminal) that is arranged at a position facing the second edge portion 13 when viewed from the thickness direction of the base 10, and is electrically connected to the semiconductor element 30 by the bonding wire 50. The distance L3 between the input signal terminal 21 and the second region 13a overlapping the input signal terminal 21 at the second edge portion 13 of the base 10 when viewed from the Z direction may be larger than the distance L4 between the input signal terminal 21 and the front surface 11a. In this configuration, it is possible to improve the frequency characteristics at both the input signal terminal 21 and the output signal terminal 23.

The output signal terminal 23 as an example is one of the plurality of output signal terminals 23. In the illustrated example, the plurality of output signal terminals 23 are a pair of output signal terminals 231 and 232. The ground terminal 16 extending from the first edge portion 12 is provided between the plurality of output signal terminals 23. In this configuration, electrical interference between the output signal terminals 23 is suppressed. That is, the isolation between the output signal terminals 23 is improved.

The peripheral edge 11c of the base 10 may include a third edge portion 14 that connects the first edge portion 12 and the second edge portion 13 to each other. The third edge portion 14 may provide the constricted portions 14a (recess portion). The power supply terminal 25 (third terminal) may be arranged in the constricted portions 14a. In this configuration, an increase in the size of the package (semiconductor device 1) is suppressed.

The semiconductor device 1 as an example includes the matching circuit board 40 that is mounted on the front surface 11a of the base 10 and electrically connected to the semiconductor element 30 and the input signal terminal 21 (output signal terminal 23). In this configuration, it is possible to perform impedance matching between the semiconductor element 30 and the input signal terminal 21 (output signal terminal 23).

The output signal terminal 23 may have the first portion 23a (first end portion) connected to the semiconductor element 30 and the second portion 23b (second end portion) facing the first portion 23a. The first portion 23a may be arranged at a position facing the first edge portion 12 in the Z direction. The second portion 23b may be arranged at a position not facing the first edge portion 12 in the Z direction. In the configuration described above, an increase in the size of the package is suppressed.

The back surface 11b may be exposed on the front surface 11a of the package covered with the resin material 60. The first portion 23a may be arranged inside the resin material 60. The second portion 23b may be exposed on the front surface 11a of the package. The output signal terminal 23 may be arranged so as to be bent in the region between the first portion 23a and the second portion 23b. In the configuration described above, an increase in the size of the package is suppressed.

While the form of an example of the present disclosure has been described in detail above, the present disclosure is not limited to the above form.

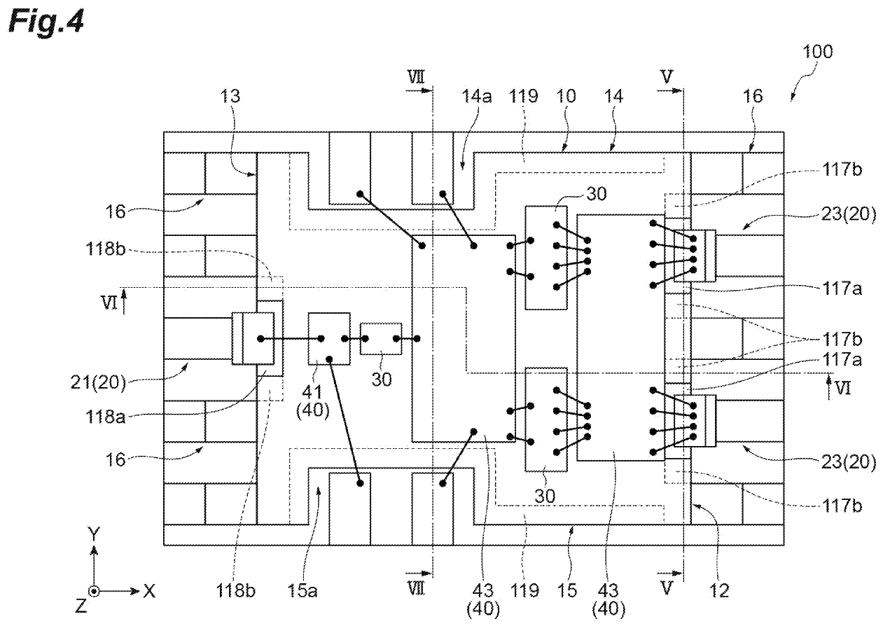

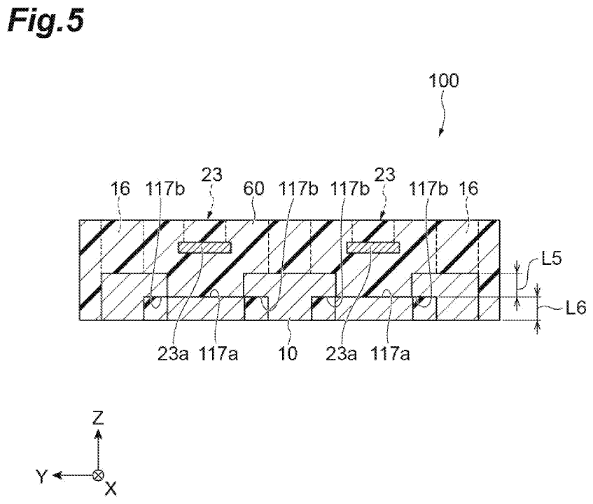

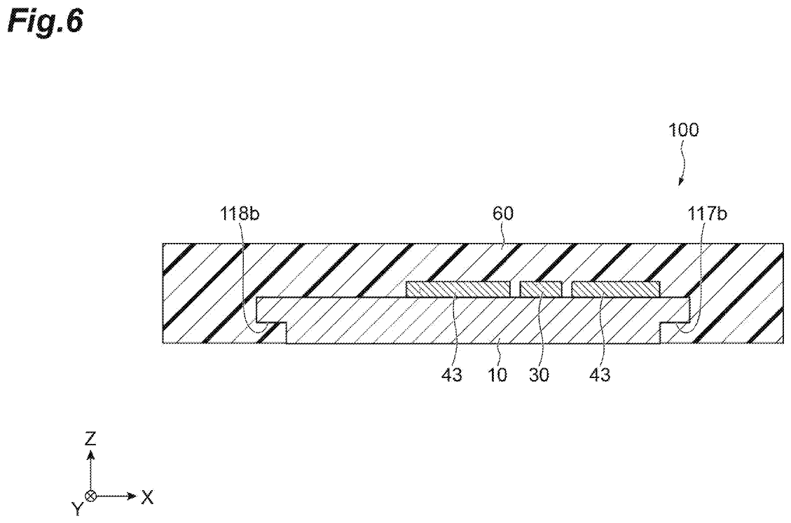

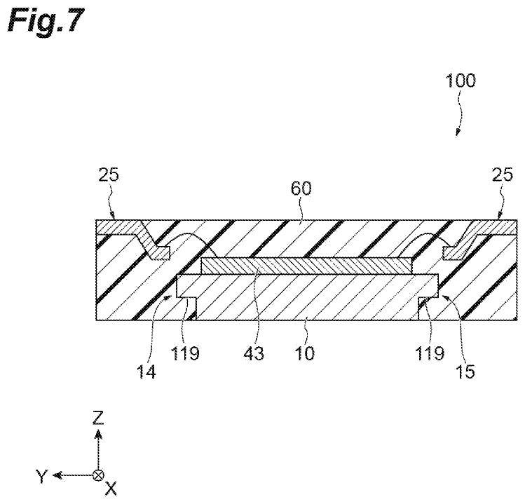

FIG. 4 is a plan view schematically showing the configuration of a semiconductor device as another example. FIG. 5 is a cross-sectional view taken along the line V-V in FIG. 4. FIG. 6 is a cross-sectional view taken along the line VI-VI in FIG. 4. FIG. 7 is a cross-sectional view taken along the line VII-VII in FIG. 4. The semiconductor devices shown in FIGS. 4 to 7 are different from the semiconductor devices shown in FIGS. 1 to 3 in that the back surface of the base has a stepped portion. In the following description of a semiconductor device 100, the description of the configuration overlapping that of the semiconductor device 1 will be omitted.

As shown in FIGS. 4 to 6, the semiconductor device 100 has a stepped portion 117a including the first region 12a overlapping the output signal terminal 23 at the first edge portion 12 of the base 10, similar to the stepped portion 17 of the semiconductor device 1. The length of the stepped portion 117a of the semiconductor device 100 in the Y direction is smaller than the length of the stepped portion 17 of the semiconductor device 1 in the Y direction. That is, in the semiconductor device 100, no stepped portion is provided over the entire region between the pair of ground terminals 16 in the Y direction, but the stepped portion 117a is provided in a region between the pair of ground terminals 16 excluding both end portions.

On the back surface 11b of the first edge portion 12, a region that does not overlap the first region 12a when viewed from the Z direction has a stepped portion 117b (first stepped portion) that is formed stepwise toward the front surface 11a. In the illustrated example, the stepped portion 117b is formed in the regions of both end portions in the Y direction between the pair of ground terminals 16. That is, the stepped portion 117b formed in the first edge portion 12 is located in a region between the stepped portion 117a and the ground terminal 16 in the Y direction. The stepped portion 117b is opened in a direction from the front surface 11a to the back surface 11b and opened in a direction from the second edge portion 13 to the first edge portion 12.

The semiconductor device 100 has a stepped portion 118a including the second region 13a overlapping the input signal terminal 21 at the second edge portion 13 of the base 10, similar to the stepped portion 18 of the semiconductor device 1. The length of the stepped portion 118a of the semiconductor device 100 in the Y direction is smaller than the length of the stepped portion 18 of the semiconductor device 1 in the Y direction. That is, in the semiconductor device 100, no stepped portion is provided over the entire region between the pair of ground terminals 16 in the Y direction, but the stepped portion 118a is provided in a region between the pair of ground terminals 16 excluding both end portions.

On the back surface 11b of the second edge portion 13, a region that does not overlap the second region 13a when viewed from the Z direction has a stepped portion 118b (second stepped portion) that is formed stepwise toward the front surface 11a. In the illustrated example, the stepped portion 118b is formed in the regions of both end portions in the Y direction between the pair of ground terminals 16. That is, the stepped portion 118b formed in the second edge portion 13 is located in a region between the stepped portion 118a and the ground terminal 16 in the Y direction. The stepped portion 118b is opened in a direction from the front surface 11a to the back surface 11b and opened in a direction from the first edge portion 12 to the second edge portion 13.

A stepped portion 119 (third stepped portion) that is formed stepwise toward the front surface 11a is formed on the back surface 11b of the third edge portion 14 and the fourth edge portion 15 of the base 10. In the illustrated example, the stepped portion 119 is formed in the regions of the third edge portion 14 and the fourth edge portion 15 of the back surface 11b excluding both end portions in the X direction. As shown in the diagram, the stepped portion 119 not only extends in the X direction, but also extends in the Y direction in accordance with the shape of constriction in the constricted portions 14a and 15a. The stepped portion 119 is opened in a direction from the front surface 11a to the back surface 11b. The stepped portion 119 is opened in the X direction or the Y direction.

In one example, the size L5 of the stepped portion 117a in the Z direction and the size L6 of the stepped portion 117b in the Z direction may be the same, and may be approximately half the thickness of the base 10, for example. Alternatively, the stepped portion 117a and the stepped portion 117b may have different sizes. The sum of the size of the stepped portion 117a and the size of the stepped portion 117b may be smaller than the thickness of the base 10.

Also in the semiconductor device 100 described above, as in the semiconductor device 1, it is possible to suppress the degradation of the high frequency characteristics. In the semiconductor device 100, in the first edge portion 12 of the base 10, the region that does not overlap the first region 12a when viewed from the Z direction has the stepped portion 117b that is formed stepwise toward the front surface 11a. In the second edge portion 13 of the base 10, the region that does not overlap the second region 13a when viewed from the Z direction has the stepped portion 118b that is formed stepwise toward the front surface 11a. In this configuration, the stepped portion 117b and the stepped portion 118b can function as anchors for the resin material 60. That is, it is possible to suppress the peeling of the resin material 60 from the base 10.

The back surface 11b of the third edge portion 14 of the base 10 may have the stepped portion 119 that is formed stepwise toward the front surface 11a. In this configuration, the stepped portion 119 can function as an anchor for the resin material 60.

What is claimed is:

1. A semiconductor device, comprising:
a semiconductor element;
a base having a first surface on which the semiconductor element is mounted and a second surface opposite to the first surface;
a first edge portion having a step from the first surface toward the second surface in a first region of a peripheral edge of the base;
a first terminal that is arranged at a position facing the first edge portion when viewed from a thickness direction of the base;
a conductive member for electrically connecting the semiconductor element and the first terminal to each other; and
a resin material for sealing a part of the base, the semiconductor element, and a part of the first terminal.

2. The semiconductor device according to claim 1, further comprising:
a second edge portion having a step from the first surface toward the second surface in a second region facing the first region of the peripheral edge of the base; and
a second terminal that is arranged at a position facing the second edge portion when viewed from the thickness direction of the base, and is electrically connected to the semiconductor element by the conductive member.

3. The semiconductor device according to claim 2,
wherein the first terminal is one of a plurality of the first terminals, and
a ground terminal extending from the first edge portion is provided between the plurality of first terminals.

4. The semiconductor device according to claim 2,
wherein the peripheral edge of the base includes a third edge portion that connects the first edge portion and the second edge portion to each other,
the third edge portion provides a recess portion; and
a third terminal is arranged in the recess portion.

5. The semiconductor device according to claim 1, further comprising:
a matching circuit mounted on the first surface of the base and electrically connected to the semiconductor element and the first terminal.

6. The semiconductor device according to claim 1,
wherein the first terminal has a first end portion connected to the semiconductor element and a second end portion facing the first end portion,
the first end portion is arranged at a position facing the first edge portion when viewed from the thickness direction of the base, and
the second end portion is arranged at a position not facing the first edge portion when viewed from the thickness direction of the base.

7. The semiconductor device according to claim 6,
Wherein the second surface is exposed on a front surface of a package covered with the resin material,
the first end portion is arranged inside the resin material,
the second end portion is exposed on a front surface of the package, and
the first terminal is arranged so as to be bent in a region between the first end portion and the second end portion.
